(19) United States
(12) Patent Application Publication
(10) Pub. No.: US 2008/0113455 A1
(43) Pub. Date: May 15, 2008

(54) Planar etching of dissimilar materials

(76) Inventors: Rajesh Jain, San Jose, CA (US); Tahir Malik, Fremont, CA (US); Vladimir Makarov, Fremont, CA (US)

Correspondence Address: DEBORAH W. WENOCUR, 4057 AMARANTA AVE., PALO ALTO, CA, 94306, US

(21) Appl. No.: 11/823,565

(22) Filed: Jun. 28, 2007

Related U.S. Application Data
(60) Provisional application No. 60/857,943, filed on Nov. 11, 2006.

(51) Int. Cl. H01L 21/306; G05D 9/00; H01L 21/02

(52) U.S. Cl. 438/8; 438/690; 700/283; 257/E21.219

(57) ABSTRACT

A method of planar etching of dissimilar materials with a Focused Ion Beam (FIB) system such as the OptiFIB manufactured by Credence Systems. The method includes adjusting the selectivity between the two materials, which varies when the ratio of the assisting chemistry pressure to the ion dose rate changes. This method can be used in such applications as FIB circuit edit, failure analysis, and cross sectioning.

### CROSS REFERENCE TO RELATED APPLICATIONS

This application is related to U.S. Provisional Application No. 60/857,943, filed on Nov. 11, 2006, and claims priority therefrom. The specification, claims, and drawings of Application No. 60/857,943 are hereby incorporated by reference in their entireties.

### FIELD OF THE INVENTION

This invention is in the field of Focused Ion Beam (FIB) applications to circuit edit and failure analysis, and in particular to balancing and tuning of etch rates in charged particle systems using assisting chemistries.

### BACKGROUND OF THE INVENTION

To maintain planar surfaces in integrated circuits during local de-processing such as is needed for circuit edit and failure analysis, etch rates must be optimized for uniform material removal of dissimilar materials. “Dissimilar Materials” are defined herein as being materials either different by their nature, or by having different morphological/crystalline forms of the same material, such as different crystallographic orientations, such that these dissimilar materials have differing etch characteristics. Examples of instances where dissimilar material types appear in IC layers include:
1) Layers in an IC consisting of more than one type of material such as dummy fill metal in dielectric planes or dielectric fill in metal planes;
2) A single material showing different properties in different regions. An example of this is a copper layer consisting of micro-crystalline grains with different crystallographic orientations which exhibit different behavior under ion beam incidence.

Modern IC manufacturing technology requires a high planarization of the IC layers. For this purpose Chemical-Mechanical Polishing (CMP) is often applied, which results in a global planarization of the layer. For CMP to be efficient, each layer which is being polished should consist “on average” of the same material in each large region across the layer, which may include for example large regions of active circuit metallization regions, and intra-level dielectric (ILD) regions. For that purpose, IC technologists include dense patterns of small metal shapes in the ILD, and also make a perforation in broad metal lines to be filled with dielectric. As a result, when doing a subsequent Circuit Edit (CE) on an IC to reach a target signal line, using a FIB system by way of example, one has to approach the edit location through layers consisting of, even on a local level, both metal and dielectric materials interleaved in close proximity. A FIB edit comprises, in part, formation of broad and narrow trenches which approach quite near the actual edit location before milling a very localized access to the exact edit spot. Use of FIB for CE is described in more detail in M. A. Thompson, C. Richardson, E. Le Roy, T. Lundquist and W. B. Thompson, ISTFA Proc. 2002 p. 409. In order to have control over the CE process, the approach to the edit location should remove the IC layers above the edit location one by one without penetrating into deeper layers. As is described in the above-cited reference, this removal is typically performed in situ, e.g. by the FIB system, not by mechanical methods such as CMP. This layer-by-layer removal of interleaved dissimilar materials is not compatible with the commonly used chemicals in chemistry assisted FIB etching, which provide highly selective removal of either dielectric vs. metal, or metal vs. dielectric. Commonly used metals in modern IC metallization include aluminum and aluminum/copper alloys, copper, and tungsten. Highly doped polysilicon is also used as a conducting interconnect material.

Other instances where dissimilar materials need to be etched in a planar way by a method less global than CMP such as FIB include: metal such as copper in proximity to a metal barrier material such as TaN or TiN; and/or dielectric over a dielectric etch stop such as silicon carbide. Both of these situations are illustrated in FIG. 1.

In modern IC's copper is generally used as a metallization material. Uniform copper removal, especially when the copper film is thick, presents a challenge for CE. Copper consists of micro-crystalline grains with various crystallographic orientations which show highly different sputtering rates under ion beam bombardment, up to a factor of 10 difference. This effect is described in J R Phillips, D P Griffis, P E Russel “Channeling effects during Focused-Ion-Beam Micro-machining of Copper”, JVSTA 18 (2000) 1061. Therefore, copper can present another case of a dissimilar materials combination as defined herein.

FIG. 2 illustrates in more detail an example of the problem, wherein Cu regions 200 are embedded in dielectric 205. The ion beam scanning region of the FIB is indicated by region 210. Mill box 215 is the three dimensional volume which is affected by the ion beam. A previous method of etching the two materials was based on the application of chemistries yielding a high etch rate selectivity of one of the two materials over the other, and the solution to obtain a planar surface was to mill each of the slower milling areas individually after removing the faster milling matrix. A more recently developed method involves first exposing a layer, for example copper containing dielectric fill. The dielectric is first overetched, then the assisting chemistry is used to protect the dielectric while the metallization is removed. This method improves the resulting planarity, but one would need to know the thickness of the dielectric to determine when to halt the dielectric etch, in order to avoid a remaining stepped trench, or a large “pedestal” under the unetched metal. No method has been offered in the literature to effectively avoid stepped trench formation or redeposition of copper on dielectric walls after removal of selectively etched material.

It is known that chemistries containing iodine, bromine, or chlorine (IBC chemicals) readily react with copper, causing corrosion, and suppress differentiation between rates of ion beam etching of different grain orientations. However, the IBC chemicals react with copper spontaneously and the area of their interaction with copper is much wider than the area where the ion beam is incident.

Methods of equalizing etch rates between dissimilar materials, of both dissimilar nature materials or dissimilar morphology materials, would be an important step both in general IC processing, and in particular as applied to circuit editing and failure analysis by Focused Ion Beam (FIB).

### SUMMARY OF THE INVENTION

In this invention, we have invented a method to adjust the selectivity of FIB chemistry assisted etching in such a way that dissimilar materials can be etched with reasonably similar rates so as to provide a planar removal of IC layers and for a planar exposure of the layer of interest at the lower level. We have further developed a computer-implemented algorithm to determine the proper conditions for a wide variety of dissimilar materials used in IC processing.

We have further utilized the above-mentioned method of selectivity adjustment with methods of verifying the flatness achieved using the methods of selectivity adjustment.

Another aspect of this invention is that we have found conditions allowing the removal of copper using an ion beam and any one of the IBC chemicals in such a way that copper layers are removed very uniformly, and spontaneous reaction of IBC-chemicals with copper is significantly reduced.

### BRIEF DESCRIPTION OF THE DRAWINGS

FIG. 1 illustrates a situation where planar dissimilar materials etching is critical, including metal embedded in dielectric, and dielectric over etch stop.

FIG. 2 illustrates the topology of Cu regions embedded in dielectric.

FIG. 3 shows the experimentally determined curves of etching rate vs. precursor pressure/ion dose rate for the two predominant copper grain orientations, (101) and (111).

FIG. 4 shows a series of micrographs demonstrating even removal of metal and dielectric over 4 layers of interconnect, by operating in the 1:1 selectivity range.

FIG. 5 illustrates metal and strong dielectric etch rates as. a function of dwell time, i.e. ion dose.

FIG. 6 is an ion beam image of non-corroded Cu.

FIG. 7a is an ion beam image of corroded Cu.

FIG. 7b shows the ion beam image as the corroded Cu is being etched away using FIB.

FIG. 7c shows the ion image of the ILD under the Cu becoming exposed as the 5 um thick Cu is milled away.

FIG. 7d shows an ion beam image of vias exposed after planar Cu removal, without etching into the next metal layer.

FIG. 8 is a flow chart of a more generalized algorithm which can be applied to dissimilar materials to provide even, i.e., planar, milling.

FIG. 9 is a diagram of the algorithm of FIG. 8, for the exemplary case of Cu over low-k dielectric.

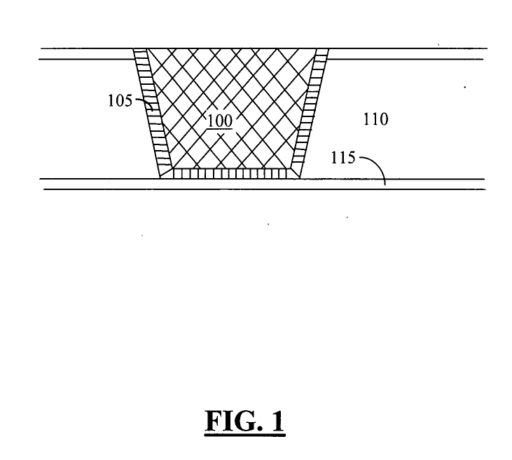

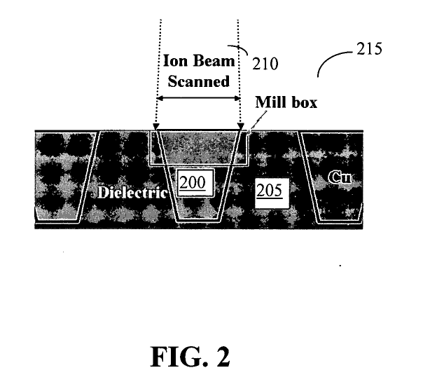

### DETAILED DESCRIPTION OF THE INVENTION

Our invention provides a set of solutions to the planar etching of dissimilar materials with a Focused Ion Beam (FIB) system such as the OptiFIB manufactured by Credence Systems. The basis of the solutions is adjusting the selectivity between the two materials, which varies when the ratio of the assisting chemistry pressure to the ion dose rate changes. Experimentally obtained curves of the selectivity vs. precursor pressure/ion dose rate are utilized. Specific solutions for three cases will be described, followed by a general description of how to determine a solution algorithm for the more general case.
1. Etching of copper over or embedded in fragile dielectrics such as low-k dielectrics.

(A fragile dielectric is defined for the purposes of this disclosure to be a dielectric which has an etch rate under sputtering only which is higher than the sputtering etch rate of the fastest-etching metal in the multi-material system, e.g., Cu(111) in the present system). This situation is encountered during layer deprocessing, where it is important to protect the deprocessed layer, i.e. the dielectric, against being completely removed during the metal etch and thereby preventing protrusion into the next layer. However, it is equally important to prevent stepped trench formation and redeposition of Cu on the dielectric walls. The preferred chemistry used in this specific case is Credence CU2 solution, which though not given the name CU2 is described in U.S. Pat. No. 7,060,196, issued Jun. 13, 2006. U.S. Pat. No. 7,060,196 is hereby incorporated by reference in its entirety. A list of possible CU2 compositions is listed in the above cited patent as: NitroEthanol, NitroEthane, NitroPropane, NitroMethane, compounds based on silazane, and compounds based on siloxane. The CU2 chemistry affects the etch selectivity between the metal and dielectric, causing a decrease in dielectric removal rate.

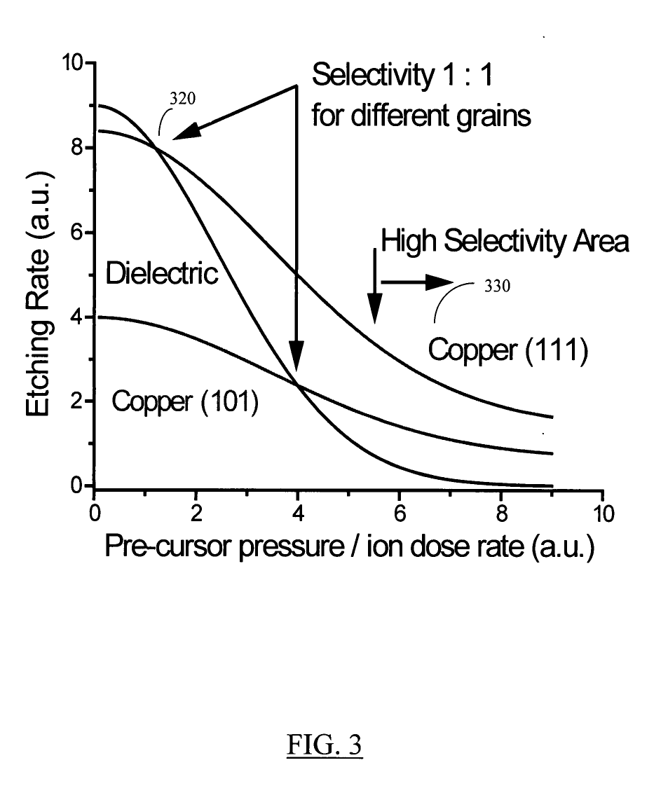

FIG. 3 shows the experimentally determined curves of etching rate vs. CU2 precursor pressure/ion dose rate for the two predominant copper grain orientations, (110) and (111). Other grain orientations such as (100) are also present, and could be similarly plotted. In this case, for planar removal of the dissimilar materials in the layer of interest, initially the ratio of pre-cursor pressure/ion dose rate (RPPID) is adjusted to the point 320 where 1:1 selectivity over the underlying dielectric is achieved for the easiest-etching copper grain orientation (111). Operating in this region during the initial etch stage, the etching proceeds until the easiest-etching copper grains have been substantially removed, and the dielectric below those grains is being exposed. At this point, for copper lines embedded in dielectric, the dielectric has been etched down very close to the level of the bottom of the copper, which greatly reduces stepped trench formation. Since the dielectric trench wall, which serve as traps for re-deposited copper, the reduction of the trenches also reduces Cu redeposition. (In contrast, earlier methods used in the Damascene process utilized chemistry which is protective of the dielectric. As a result, the FIB only removed the Cu, leaving behind trenches.) However, there is still copper remaining of the other orientations. Therefore, after a noticeable amount of copper is removed and a noticeable underlying dielectric is exposed, the RPPID is adjusted to a high number, and selectivity of copper etch rate to dielectric etch rate is increased, moving into High Selectivity Area 330. This removes the remaining copper, while protecting the exposed dielectric. More details of this process are described in Development of a Circuit Edit Process Scalable in Dimension and Material, Vladimir Makarov and Nicholas Antoniou, Proc. 32^{nd} ISTFA, 2006, pg. 62, which is hereby incorporated by reference in its entirety. (Further description of the etching of copper on or in low-k dielectric is found in T. Ohuchi et al, LSI Testing Symposium, 2003, pg. 107 (Osaka, Japan), which is hereby incorporated by reference). In the case of a uniform copper layer over a dielectric layer as opposed to embedded copper, the same process can be followed, as a means of increasing the effectiveness of the underlying dielectric layer as a copper etch stop and preventing etching through the dielectric layer.

The typical working parameters in this case are the ion beam current density J, and the CU2 gas pressure P. To be in high selectivity region 330, J should be 5 pA/um2 or lower, and P should be 2×10−1 Torr or higher in the spot under the gas delivery nozzle, estimated based on a chamber precursor pressure of 1 to 5×10−5 Torr. To reach the high selectivity region 330 when starting from point 320 with approximately 1:1 selectivity between dielectric and (111) copper grains, either current density should be decreased by a factor of about 3, or precursor pressure should be increased by a factor of about 3. Experimental evidence shows that selectivity tends to be approximately inversely proportional to current density and approximately directly proportional to pressure in the normal operation range.

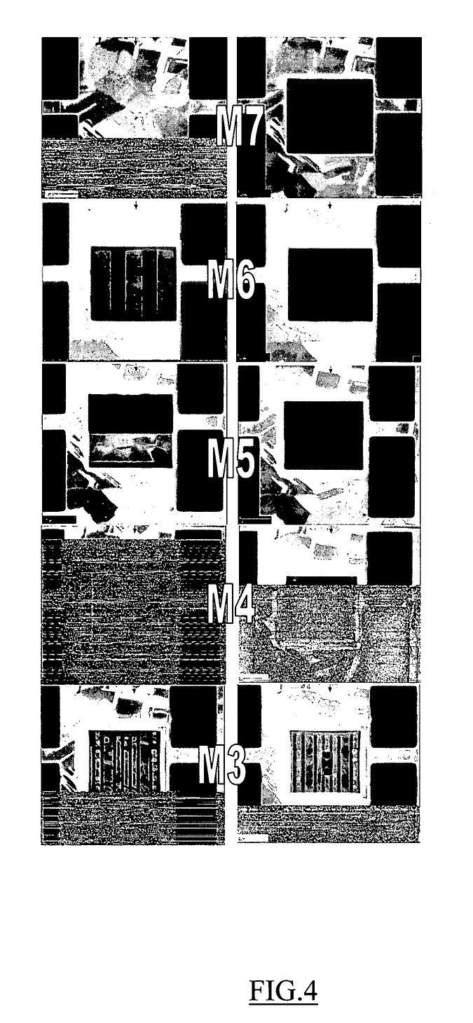

FIG. 4 shows a series of micrographs demonstrating even removal of metal and dielectric over 4 layers of interconnect, by operating in the 1:1 selectivity range. In these micrographs, ILD7 is SiO₂, all the others are low-k dielectric.
2. Etching of metal (copper or aluminum) over or embedded in a physically strong dielectric such as: SiO₂, silicon nitride, silicon oxynitride, Fluorinated Silicon Glass (FSG), and other non-organic dielectrics. A strong dielectric is defined herein as a dielectric which has an etch rate under sputtering only which is lower than the sputtering etch rate of the slowest-etching metal in the multi-material system. For example, in the case of Cu, more slowly than Cu (100).

In this case, layer deprocessing is accomplished using XeF₂ in conjunction with the ion beam. The reason for this choice of chemistry is described below. Selectivity adjustment allows for faster de-processing of the dissimilar material layers. Also, using the XeF₂ chemistry, redeposition will be continuously being removed, and with the fluorine chemistry, there will be essentially no conductive copper on the trench sidewalls.

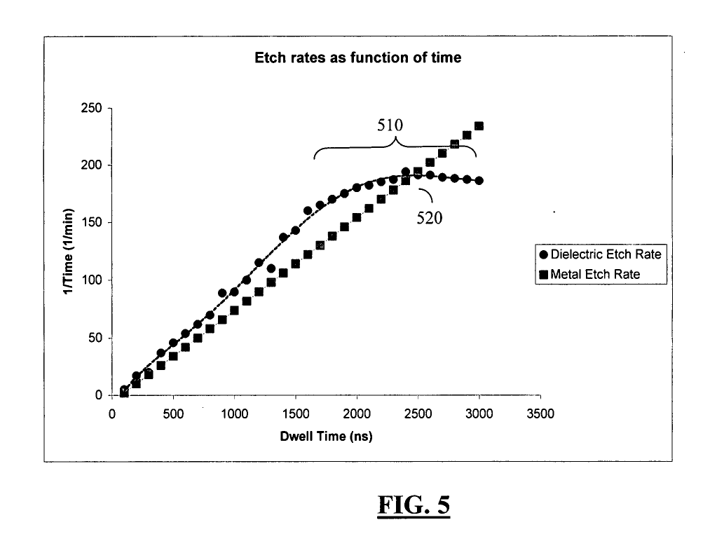

This technique takes advantage of the fact that, for strong enough dielectrics, the pure sputtering rate for both copper and aluminum is higher than for the ILD's. However, when a fluorine based chemistry such as XeF₂ is used along with the ion beam, the Si based ILD's etch faster than the metals. The enhancement in the etch rate occurs due to a highly localized chemical reaction between the Si and the fluorine. This effect is illustrated in FIG. 5. Up to a threshold ion dose, the etch rate of the ILD increases with the ion dose at a constant dose of the chemistry. But, beyond a threshold limit of ion dose, the utilization of the available chemistry in the localized region is 100%. At that point, the etch rate of the ILD stops increasing and levels off. This is known as “depleted region” or chemistry limited region 510. The metal etch rate continues to increase with ion dose, however, since the metal etch is basically completely due to sputtering. Consequently, at point 520, the metal etch rate equals the ILD etch rate. Therefore, in this case the way to achieve equal etch rates for the two dissimilar materials is to tune the ion dose or dwell time. As in the previous case, the process is accomplished at room temperature in a vacuum <1×10−5 Torr with chemistry flow rate corresponding to a chamber pressure of about 5×10−5 Torr, and approximately 5×10−1 Torr directly under the gas delivery nozzle. Typical working parameters for a 10×10 um. box for both Cu and SiO2 are:

| | |
|---|---|
| 1. Beam Current | 1 nA |
| beam current density | 10 pA/um2 preferred, range 5-20 pA/um2 |
| 2. XeF2 Chemistry pressure | 2 × 10−5 Torr preferred, range 9 × 10−6 |
| | to 9 × 10−5 Torr |
| 3. Box size: | 10 um × 10 um preferred, range >1 × 1 um |
| 4. Beam Spot Size | 250 nm (the bigger the better: 5 nm −1 |
| | micron or larger if beam is defocused) |
| 5. Pixel Dwell Time | 6 usec to>50 nanosec, less than 1 msec |
| 6. Pixels | 512 × 512 or higher |
| 7. Retrace time | 725 msec to >.4 usec |

8. The parameters can be worked out for any box size.

A preferred calibration technique is: Using no chemistry, etch ILD and record time T (etch dielectric), i.e. the time to etch through the dielectric. Then etch Cu and record time T(etch Cu), i.e. the time to etch through the fastest etching grains. If T(etch dielectric)>T(etch Cu), then we may proceed with a software routine, which will use the measured times to calculate the parameters for the etch for a given Box size. It will predict beam current, pressure, dwell time, pixels, and retrace time. The parameters are only process dependent and not device dependent. For example: the algorithm would set T(etch dielectric)/T(etch Cu) as a function of beam current density: Beam current density as a function of XeF₂ pressure; beam current density as a function of 1/pixel dwell time; beam current density as a function of 1/pixels. These functions are experimentally determined, and are tied to the process. Since removal rates are material-dependent, the numbers and functions can be different for every layer in a given process.

This case of the strong dielectric vs. metal differs from the previous case of fragile low-K dielectrics vs. metal, in that the fragile ILD's sputter faster than the metal even under the ion beam only, with no chemistry assistance. Therefore, in the case of metal over fragile dielectrics, to achieve equal etch rates, a sputter retardant is used for the ILD, rather than an enhancing chemistry. In contrast, for the case of strong dielectrics, to achieve equal etch rates, the dielectric etch rate must be enhanced, which is achieved using the XeF2. The process flow is similar to the process flow for etching Cu over fragile dielectric. The main difference is that, in the case of Cu over fragile dielectric, the first step is to adjust the chemistry to raise the etch rate of the Cu relative to the dielectric, so as to equalize the dielectric etch rate with that of the fastest-etching Cu grain, that is, Cu(111). This is necessary since the pure sputtering rate of the fastest-etching Cu grain is lower than the pure sputtering rate of the fragile dielectric. In contrast, in the case of Cu over strong dielectric, the first step is to adjust the chemistry to lower the etch rate of the Cu relative to the dielectric, so as to equalize the dielectric etch rate with that of the slowest-etching Cu grain, that is, Cu(100). This is necessary since the pure sputtering rate of the slowest-etching Cu grain is higher than the pure sputtering rate of the strong dielectric. In the case of the fragile dielectric, the chemistry and ion dose are then changed so as to move into the region of high selectivity, i.e., much higher etch rate of Cu than of dielectric, for the remaining Cu orientations while the remainder of the Cu is removed. This step is not necessary for the strong dielectric, since when the slowest etching Cu grains, the Cu(100) grains, are removed, the faster etching Cu grains, the Cu(110) and Cu (111) grains, are also removed.
3. Thick copper removal

We have developed a method to use the spontaneous corrosion of Cu by halogens to very effectively and in a controlled way remove large, thick Cu areas. It is known that using a normal incidence ion beam, different Cu grain orientations have different etch rates, as described in S. B. Herschbein, L. S. Fisher, T. L. Kane, M. P. Tenney, and A. D. Shore, ASM-ISTFA (1998), 127. It is also known (see the above reference) that exposing a micro-crystalline Cu surface to a halogen chemistry can be used to destroy the Cu grain structure by corrosion. Corrosion, however, has not been utilized in the past to equalize the etch rates of the different Cu orientations. This is due mainly to the lack of control of the corrosion as applied to previous structures and with previous chemistries. If corrosion is not properly controlled, which is particularly critical for thinner Cu lines, it may remove material beyond the structures it is intended to remove. The technique described above is only applicable for thick Cu plane removal—greater than about 1.5 um, wherein the corrosion depth can be controlled due to the large bulk of the material. Structures such as RDL's (ReDistribution Layers) which have thicknesses up to about 10 microns and which therefore can successfully utilize the above corrosion technique have only recently been incorporated into I. Additionally, previous corrosion methods have used pure iodine chemistry, as opposed to Credence's EDI (ethylene-di-iodide) chemistry. An example of this is described in U.S. Pat. No. 6,730,237, issued May 4, 2004. Pure iodine seems to be more corrosive than the bonded iodine in EDI.

We have found that by exposing Cu to a bound halogen-containing chemistry such as EDI, while simultaneously removing copper using an ion beam, one can adjust the ion dose rate in such a way that the material removal rate is equal or slightly higher than the corrosion rate. When this is done, the differential etch rates no longer occur, and the thick Cu can be removed uniformly. Benefits of this method of copper removal include: 1) conducting corroded copper material re-deposition is minimized, since using the disclosed chemistry, the majority of any re-deposited material would be in the form of a CuI compound, which is non-conductive, and 2) corrosion protrusion to the walls of the trench in the copper layer is minimized (see point 3) following). 3) since the corroded Cu is being removed continuously as it forms, the danger of uncontrolled corrosion is greatly decreased. Since the bound halogen chemistry which induces the corrosion is associated with the FIB, as soon as the FIB milling ceases, the corrosion also is significantly quenched.

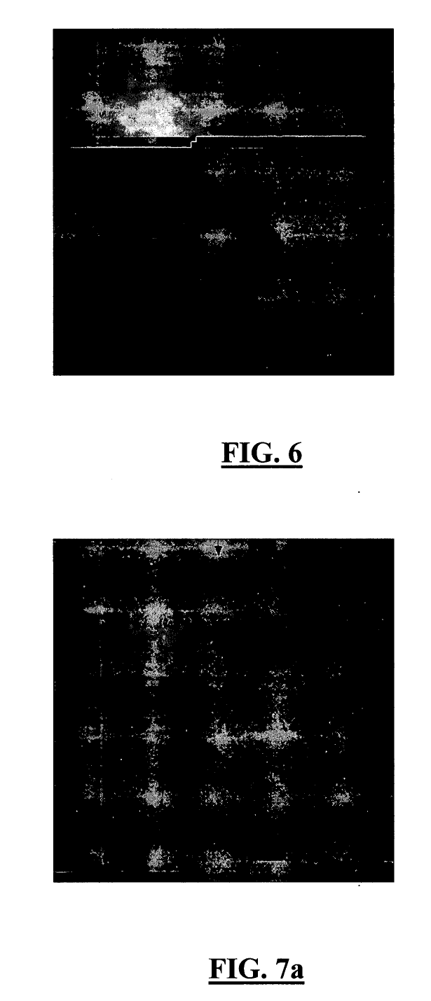

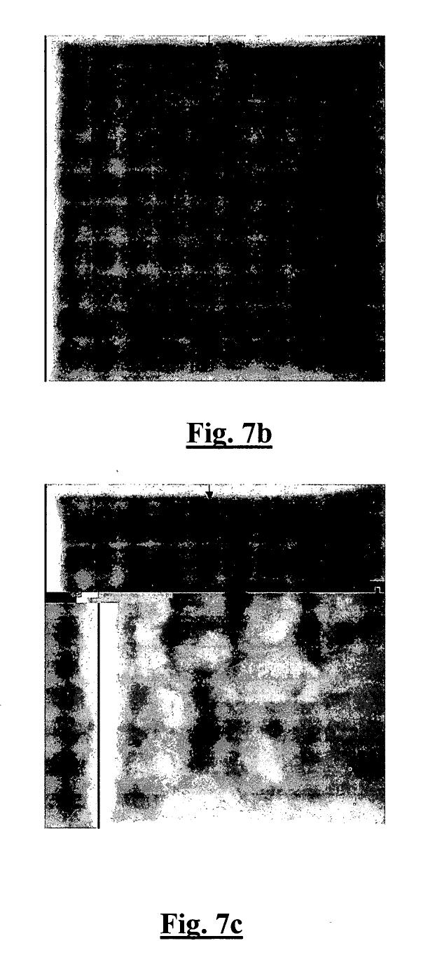

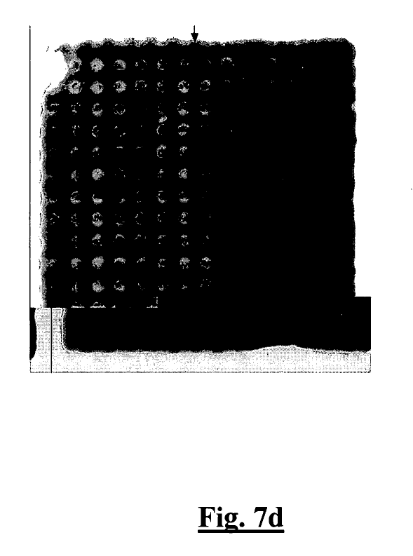

Adjusting the chemistry pressure and the ion beam scanning parameters (beam current, pixelation, dwell time, pixel overlap, retrace time) so as to successfully equalize the material removal rate and the corrosion rate can be done using the ion beam image. It is proposed that the chemistry pressure and ion beam scanning parameters should be adjusted in such a way that in the ion beam image of copper surface under the process, copper micro-crystal grain structure would be significantly blurred by corrosion, but still show up. This image situation corresponds to a very thin corroded layer, indicating that the corrosion rate and removal rate are substantially equal. The ion beam image of non-corroded Cu is seen in FIG. 6. Corroded Cu appears on the ion beam image as seen in FIG. 7a. FIG. 7b shows the ion beam image as the corroded Cu is being etched away using FIB, and FIG. 7c shows the ILD under the Cu becoming exposed as the 5 um thick Cu is milled away. FIG. 7d shows an ion image of vias exposed after planar Cu removal, without etching into the next metal layer.

As shown above, the ion beam image can indicate the removal of corroded Cu. However, if an optical image is available, there is an advantage to using the optical image as well as the FIB image for monitoring the copper corrosion/removal process. Optical reflectivity of the Cu surface, which is visible on the optical image but not the FIB image, shows the clearest indication of corrosion intensity, as follows: During EDI Cu mill operation the Optical image at ˜700 nm wavelength filter would look “grayish” (it may have a variation of brighter and darker areas/grains). As there are areas or Cu grains that are getting corroded and removed; the reflection of light from the surface is low as the Cu is getting corroded, and is higher/brighter as it's freshly removed/etched. This continuous variation of somewhat darker and somewhat brighter areas/grains can be used to optimize the Cu corrosion/removal rate:

If the Cu areas are mostly remaining “brighter” in the optical view then there is less corrosion happening and Cu is being etched mostly with ion beam sputtering. This “sputtering” process will cause non-planar Cu removal depending on the grain orientations, as has been earlier described.

If the Cu areas are mostly remaining “dark” in the optical view then there is a lot of corrosion happening, i.e. too much chemistry reacting without Cu being etched away. This corrosion could grow deeper if not removed with the ion beam completely in the presence of the chemistry. The Cu “corrosion depth” may vary based on the grain orientation. If the Cu plane is left to corrode without a concurrent optimized ion mill process, then variations in corrosion areas will cause non-planar Cu plane removal.

Ideally, a very thin corrosion layer is continually being formed and removed to perform planar Cu bus removal. This results in a “grayish” optical image with the Cu grains varying between a little bit darker and a little bit brighter during the whole process. The optical image of pure Cu appears bright with granularity. A fully corroded surface appears dark and splotchy, with greatly decreased reflectivity. For balanced controlled corrosion/removal, the optical image appears mostly light, with shifting dark regions.

In a preferred embodiment, observation of both the optical image and the ion image can be performed in situ using the combined optical/ion beam system called the OptiFIB by Credence. Typical working parameters for this method using a 25 um×25 um box are:

| | |
|---|---|
| Beam current: | 12 nA (range 8 nA to 15 nA) |
| Chemistry pressure: | 8 × 10 −6 to 6 × 10−5 Torr, for any IBC |
| | chemistry |
| Box size | 25 um × 25 um |
| Beam spot size | 1.9 um (range 1 um to 2.5 um) |
| Pixel dwell time | 11 usec (range 10 usec to 12 usec |
| Retrace time | 725 msec (range 100 msec to 900 msec) |
| Pixel overlap | 95% (range 90% to 97%) |

### For different box sizes the software will provide the optimal parameters.

If these parameters are optimized, the ion beam keeps working in chemistry depletion mode. As the beam is scanning through an area, it leaves newly-exposed Cu, and in the time that the beam returns to the same area after rastering the complete box, the Cu surface has been corroded by the IBC gas's spontaneous reaction to the exposed material. In this way, the ion beam is always etching away just the thin corroded layer of Cu that developed using the corrosive chemistry in the absence of the ion beam.

The critical considerations for this process are:
1) To give enough time for the chemistry to react with the Cu spontaneously and to develop a corrosion layer:
2) To achieve a certain thickness to be able to be evenly removed by the ion beam. Experimental results show that the removal rate and uniformity is optimized for a corroded layer thickness in the range between about 1 nm to 100 nm. A thicker corroded layer is found to be hard to remove and to remove evenly; a thinner corroded layer behaves similarly to pure sputtering. As long as each corrosion layer is completely removed by the ion beam for every scan, the process will work effectively.

The ion beam has to work in chemistry depletion mode in order to remove the corroded material. If that were not the case, the corrosion would continue as the ion beam was removing the corroded material and it could never be completely removed, as is required by point 2 above. We believe that silver can most likely be removed by a method similar to the copper removal method because of the similarities between copper and silver, which is used in some solar cell devices.

Further details about the three specific processes disclosed herein, as well as the general algorithm for de-processing of dissimilar materials, are found hereinafter.

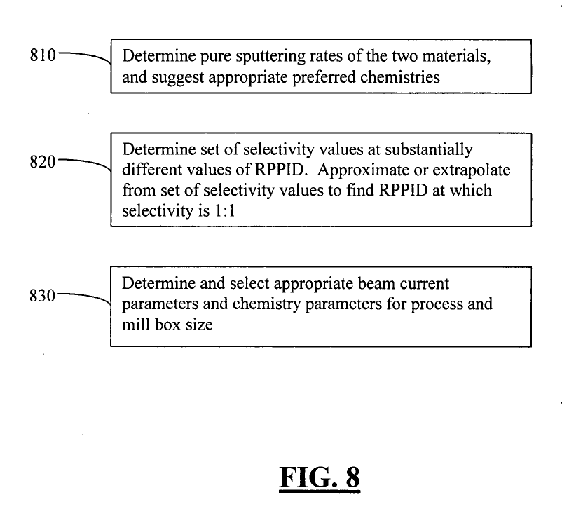

From these three examples, a more generalized algorithm can be generated which can be applied to dissimilar materials to provide even, i.e., planar, milling. The algorithm can be implemented as computer-coded software, and can be used to guide a step-by-step process for a FIB user to set up the milling conditions and execute the needed parameters, under computer control. This generalized algorithm is summarized in FIG. 8:

In step 810, an analysis procedure is followed for the software to determine the pure sputtering rates (i.e., without added chemistry) of the two materials, (which may be obtained from library files, or determined experimentally in situ), and to then suggest the appropriate chemistries, e.g., XeF₂ if the dielectric sputters slower than the metal, a retarding chemistry such as CU2 if the dielectric sputters faster than the metal. Special cases can be included in the database, e.g., although W sputters slower than even SiO₂, XeF₂ is the best chemistry choice, since W removal rate actually increases faster with XeF₂ than does the SiO₂ removal rate. Another special case is the case of producing copper corrosion.

In step 820, the preferred chemistry is used to experimentally determine a set of selectivity values measured at substantially different values of RPPID. The computer software can aid in approximating between the experimental values or extrapolate beyond the experimental values, to calculate or calibrate the precursor pressure/ion dose point (RPPID) at which the selectivity is 1:1 between the two dissimilar materials. This can also be input from library files. With this RPPID value the computer with knowledge of the box size selected by the user, controlling chemistry pressure and beam currents with corresponding beam diameters can chose the chemistry pressure, beam current, number of pixels, pixel dwell time and refresh time for the box size selected by the user in such a way that RPPID is equal to the required number. The RPPID is the ratio of the gas flux to Ion Dose Rate. The computer can control this ratio by changing either or both of these parameters. Particularly, the Ion Dose Rate is a known function of ion current, box geometry, number of pixels in the box, dwell time and retrace time of the beam scan. Also, working gas local pressure can be changed by opening/closing valves and changing positioning of the gas jet with respect to the operation area.

In the case of the controlled corrosion, the corrosion itself effectively equalizes the etch rates of the different microcrystal grain orientations by destroying the crystallinity.

In step 830, the computer software determines and selects the appropriate beam current parameters (beam current, dwell times, refresh times, pixel spacings/pixel count, scan orientations, etc.) and also the chemistry parameters (pressure, injector distance) based on the process being edited, for the mill box size selected. Note that the mill box is the area exposed to the ion beam where the FIB operation is performed. Pixel numbers are selected by software in such a way that beam tails do not become an issue. As necessary the computer can modify slightly the box size for full optimization. This computer selection of parameters is based on the following capabilities of the software controlling the system:

The computer knows at what temperature to run the chemistry sources to increase or decrease the chemistry flux by a certain amount—controlling chemistry pressure.

From a look up table the computer knows the effective interaction diameter of each beam current. From this information the number of pixels in a mill box can be determined.

RPPID=k (Precursor pressure/Box area)/ID, where ID is ion dose rate; where the x,y Box size (Box area=xy) is determined by the user

where ID=ID (I_{BC}, Dwell time DT, number of pixels, refresh time RT, etc.);

ID=I_{BC}X(DT/RT)

For each chemistry, there is a time at which the chemistry on the surface is almost saturated for that chemistry precursor pressure, the material, the temperature etc. The refresh time must allow for the chemistry to be almost saturated. If the refresh time is less than the saturation time then adjustments must be bad to the beam dwell time.

For a larger I_{BC}, pixel spacing is increased (as larger beam currents generally have the beam current spread over a larger area) so as to maintain the ideal value to make S=1. Alternatively for larger I_{BC} the dwell time can be reduced so that the larger beam current does not stay as long. Alternatively the chemistry flux can be increased by increasing the flow.

As the number of pixels is always a whole number, the software code can decrease slightly the mill box so this whole number constraint can be completed without impacting optimization. Note the box is always decreased so as not to impact the edit design of the user. If the box (especially when the box has few pixels as for, e.g., a high aspect ratio hole) is made larger then the edit might nick a trace it needs to by-pass.

Generally the chemistry pressure is not touched as it is slow to respond; but for some large mill boxes it may need to be decreased because the total beam current is insufficient otherwise or for some small mill boxes it may need to be reduced. Note there can be certain system settings which can enable a very fast change for a very particular ΔP—the computer knows these.

Often, for alignment reasons, the user does not want to change the beam current, thus the computer must optimize for this condition.

The fewer the number of pixels the more difficult it is to visualize the milling, thus it is desirable to have more than about 256×256 pixels in a mill box.

What the computer should do therefore is to provide the user with alternatives such as keeping the beam current fixed, keeping pressure fixed, maximizing the number of pixels, etc.

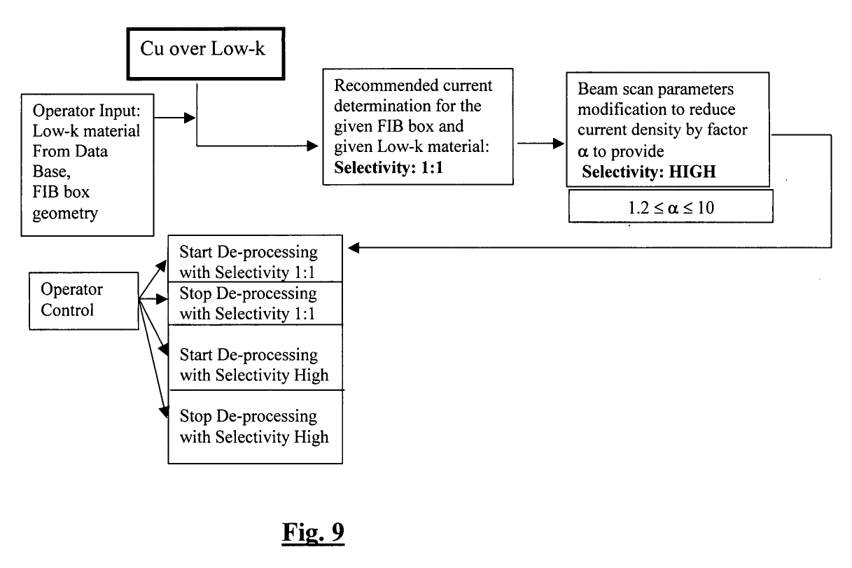

A diagram of the algorithm is illustrated in FIG. 9, for the exemplary case of Cu over low-k dielectric. In order to address other cases, an additional algorithm step which determines if a switch of selectivity points will be necessary, and under what conditions, should be added. Note further that modifications to the basic algorithm can be performed in order to address more complex situations, for example if three materials need to be etched in a planar way in close proximity. An example of this might be copper embedded in a dielectric, but with a layer of copper barrier material such as tantalum between the copper and the dielectric.

A further improvement in the utility of using this algorithm set is to build a library of selectivity curves for different materials combinations found in IC processing. This library can be stored in a computer, and accessed when implementing the algorithm set described herein.

This invention provides a method to adjust the selectivity of FIB chemistry assisted etching in such a way that different-etching materials can be etched with reasonably similar rates so as to provide a planar removal of IC layers and for a planar exposure of the layer of interest at the lower level. It further provides a computer-implemented algorithm to determine the proper conditions for a wide variety of different-etching materials used in IC processing.

A partial list of materials combinations for which this invention is applicable includes:
1. Bulk metal
2. Metal over/embedded in strong dielectric
3. metal over/embedded in weak dielectric
4. metal and metal barrier material, possibly embedded in dielectric
5. dielectric and dieclectric etch stop

A partial list of materials for which this invention is applicable includes:
1. Metals: copper, tungsten, aluminum, aluminum/Cu alloy, polysilicon including highly doped n- or p- type polysilicon, gold, silver; metals to be used for interconnect, intraconnect, dummy, RDL (redistribution layer)
2. Dielectric: strong dielectric; SiO2, Si3N4, Fluorinated Silicon Glass (FSG), hafnium oxide, high-k dielectric; fragile dielectric; Carbon Doped Oxide (CDO), Coral™, Black Diamond™, Silk™, low-k dielectric
3. Barrier material: tantalum, tantalum oxide, titanium, Titanium nitride
4. Dielectric etch stop: silicon carbide, silicon nitride
5. Etch chemistries: Ammonium Hydroxide, water, XeF2, NitroEthanol, NitroMethane, NitroEthane, NitroButane, NitroPropanol, Iodine, iodine compounds, di-iodo-ethane, Bromine, bromine compounds, Chlorine, chlorine compounds, EDI, compounds based on silazane, and compounds based on siloxane.

The methods described in this application can be utilized for the following purposes:
1. For planar deprocessing for failure analysis or circuit edit using a FIB process
2. For performing actual FIB cross sectioning
3. For performing virtual FIB cross sectioning, as described in U.S. Provisional application No. 60/733,812, filed Nov. 11, 2005, PCT application No. PCT/CA2005/001733, filed Nov. 15, 2005, and U.S. provisional application No. 60/876,790, filed Dec. 22, 2006. All three of these applications are hereby incorporated by reference in their entireties.

An improvement in the above-disclosed implementation adds verification of planarity during and after the etch process. One method for doing this involves the observation of optical fringes, which can appear during the actual etch. The fringes can be used, not only to estimate when an etch endpoint is near, but also to determine flatness of a trench bottom. This is done by noting the fringe spacing and also its contrast and its movement with time. This technique is described in U.S. Pat. No. 7,115,426, issued Oct. 3, 2006, which is hereby incorporated by reference. Optical thickness measurements can also be performed at several points across the trench bottom to determine flatness, if dielectric rather than metal is exposed. Also, some flatness data can be obtained from the FIB image.

The invention is not restricted to the exact embodiments disclosed herein. It should be apparent to those skilled in the art that modifications may be made without departing from the inventive concept. By way of example, the method may be applicable to materials and processes not specifically listed above. The scope of the invention should be construed in view of the claims.

With this in mind, we claim:

1. A method of etching at least two dissimilar materials on a semiconductor sample, each of said at least two dissimilar materials etching at an associated etch rate, the method comprising:
a) directing a charged particle beam having an ion dose rate and a particle beam flux at an area of said sample, said charged particle beam causing each of said at least two dissimilar materials to undergo sputtering at an associated sputter rate;
b) exposing said area of said sample to a pre-cursor pressure of vapors of a chemical compound selected to provide a chemistry to assist in etching of said materials, said charged particle beam directed at an area of said sample combined with the assistance of said chemistry yielding said associated etch rates for each of said materials;
c) adjusting the ratio of said pre-cursor pressure and said ion dose rate (RPPID) in such a way as to cause said associated etch rates of two of said at least two dissimilar materials to be similar to each other.

2. The method of claim 1, wherein:
steps a), b), and c) comprise;
i) determining the pure sputtering rates of each of said at least two dissimilar materials;
ii) determining a preferred said chemistry dependent on said at least two dissimilar materials;
iii) using said preferred chemistry to determine the RPPID at which etch selectivity is 1:1 between the two dissimilar materials.
iv) selecting a mill box size; and
v) determining and selecting appropriate beam parameters and chemistry parameters for the mill box size selected.

3. The method of claim 2, wherein the determinations of steps i) and iii) are obtained using library files.

4. The method of claim 2, wherein the determinations of steps iii) and v) utilize a computer and associated software.

5. The method of claim 4, wherein said computer and associated software is configured to determine the RPPID at which etch selectivity is 1:1 between the two dissimilar materials by performing the steps of:
a) inputting a plurality of experimental data for preferred chemistry-dependent selectivity values for the two dissimilar materials measured at a plurality of substantially different RPPID values, wherein one of said RPPID values is equal to 0;
b) approximating said etch selectivity as a function of RPPID within the range of the RPPID values of said experimental data;
c) extrapolating said function of RPPID beyond the range of the RPPID values of said experimental data;
d) finding the value of RPPID for which the etch selectivity is equal to 1; and
e) finding the optimal values of chemistry pressure, beam current, number of pixels, pixel dwell time, and refresh time for the selected box size to provide said RPPID value for which the etch selectivity is equal to 1.

6. The method of claim 2, wherein said beam parameters include: beam current, dwell times, refresh times, pixel spacings/pixel count, and scan orientations; and wherein said chemistry parameters include pressure and injector distance.

7. The method of claim 1, wherein the combination of said first and second of said at least two dissimilar materials are chosen from the group consisting of: a bulk metal and a bulk metal; a metal and a strong dielectric; a metal and a fragile dielectric; a metal and a metal barrier material; and a dielectric and a dielectric etch stop.

8. The method of claim 1, wherein said chemistry enhances a first said etch rate of a first of said at least two dissimilar materials relative to a second said etch rate of a second of said at least two dissimilar materials.

9. The method of claim 1, wherein said chemistry retards a first said etch rate of a first of said at least two dissimilar materials relative to a second said etch rate of a second of said at least two dissimilar materials.

10. The method of claim 8, wherein said first of said at least two dissimilar materials is a strong dielectric, and said second of said at least two dissimilar materials is a metal.

11. The method of claim 10, wherein said strong dielectric is chosen from the group consisting of: SiO2, Si3N4, Fluorinated Silicon Glass (FSG), hafnium oxide, and high-k dielectric, and said metal is chosen from the group consisting of: copper, tungsten, aluminum, aluminum/Cu alloy, polysilicon, gold, silver; interconnect metal, intraconnect metal, dummy, and RDL.

12. The method of claim 11, wherein said strong dielectric is SiO2, and said metal is copper (100) grains.

13. The method of claim 12, wherein said at least two dissimilar materials further includes Cu(111) grains and Cu(110) grains.

14. The method of claim 12, wherein said chemical compound is XeF2.

15. The method of claim 13, further comprising the steps of:
a) adjusting the ion dose rate at a constant precursor pressure to provide 1:1 selectivity between Cu(100) and said strong dielectric; and
b) etching until the Cu(100) grains have been substantially removed, said strong dielectric under said Cu(100) grains being thereby exposed.

16. The method of claim 9, wherein said first of said two dissimilar materials is a fragile dielectric, and said second of said two dissimilar materials is a metal.

17. The method of claim 16, wherein said fragile dielectric is chosen from the group consisting of: Carbon Doped Oxide (CDO), Coral™, Black Diamond™, Silk™, low-k dielectric, and said metal is chosen from the group consisting of: copper, tungsten, aluminum, aluminum/Cu alloy, polysilicon, gold, silver; interconnect metal, intraconnect metal, dummy, and RDL.

18. The method of claim 17, wherein said fragile dielectric is low-k dielectric, and said metal is copper (111) grains, and wherein at least a portion of said fragile dielectric is below said metal.

19. The method of claim 18, wherein said at least two dissimilar materials further include Cu(100) grains and Cu(110) grains, wherein said chemical compound is chosen from the list consisting of: NitroEthanol, NitroEthane, NitroPropane, NitroMethane, compounds based on silazane, and compounds based on siloxane; and further comprising the steps of:
f) adjusting the ratio of pre-cursor pressure/ion dose rate (RPPID) to provide 1:1 selectivity between Cu(111) and said fragile dielectric;
g) etching until the Cu(111) grains have been substantially removed, said fragile dielectric under said Cu(111) grains being thereby exposed;
h) adjusting said RPPID to a high number to provide a high selectivity between Cu(100) and said fragile dielectric and between Cu(110) and said fragile dielectric; and
i) etching until said Cu(100) grains and said Cu(110) grains have been substantially removed.

20. The method of claim 1, wherein said first of said at least two dissimilar materials is a first crystalline orientation of Cu, and said second of said at least two dissimilar materials is a second crystalline orientation of Cu.

21. The method of claim 20, wherein said chemistry utilizes a halogen-containing chemical compound.

22. The method of claim 21, further comprising the steps of:
a) exposing said Cu to said halogen-containing chemical compound to induce corrosion of said Cu at a corrosion rate, while simultaneously removing corroded Cu with said charged particle beam; and
b) adjusting said ion dose rate so that the rate of removal of said corroded Cu is substantially equal to said corrosion rate.

23. The method of claim 22, wherein the step of adjusting said ion dose rate so that the rate of removal of said corroded Cu is substantially equal to said corrosion rate includes using both optical and ion images of said Cu to equalize said rate of removal of said corroded Cu with said corrosion rate.

24. The method of claim 1, further including the step of verifying planarity during and after said etching.

25. The method of claim 24, wherein said step of verifying planarity curing and after said etching comprises performing optical thickness measurements at several points across the region being etched.

26. A FIB planar deprocessing process for failure analysis including the method of claim 1.

27. A FIB planar deprocessing process for circuit edit including the method of claim 1.

28. A computer configured to:
control a charged particle beam having an ion dose rate and a particle beam flux directed at an area of a sample comprising at least two dissimilar materials, said area comprising a mill box having a size, and to control exposing said area of said sample to a pre-cursor pressure of vapors of a chemical compound selected to provide a chemistry to assist in etching of said at least two dissimilar materials, wherein said computer and associated software performs the tasks of:
a) determining the pure sputtering rates of each of said at least two dissimilar materials; and
b) determining and selecting appropriate beam parameters and chemistry parameters for said mill box size.
